(19) United States
(12) Patent Application Publication
(10) Pub. No.: US 2004/0070959 A1
(43) Pub. Date: Apr. 15, 2004

(54) Multi-layer board, its production method, and mobile device using multi-layer board

(76) Inventor: Hiroshi Sakai, Toyota-city (JP)

Correspondence Address: POSZ & BETHARDS, PLC, 11250 ROGER BACON DRIVE, SUITE 10, RESTON, VA, 20190, US

(21) Appl. No.: 10/667,403

(22) Filed: Sep. 23, 2003

(30) Foreign Application Priority Data
Oct. 15, 2002 (JP) 2002-300700

(51) Int. Cl. H05K 1/11; H05K 1/14

(52) U.S. Cl. 361/792

(57) ABSTRACT

A plurality of one-sided conductive pattern films made of resin films are piled up to form a pile with sandwiching in a given region a release film that is easily released from the resin films. The pile is then heated and pressurized to form a multi-layer board. After components are mounted on the surface of the multi-layer board, the multi-layer board and the release film are separated from each other. At least one separation board is then folded at an angle relative to a position prior to being separated. Components are mounted on the released surfaces of the separation boards. Thus, newly mounting the components on the released surfaces of the separation boards enables high-density mounting without enlarging the superficial dimensions of the multi-layer itself and adding a new board.

### CROSS REFERENCE TO RELATED APPLICATIONS

This application is based on and incorporates herein by reference Japanese Patent Application No. 2002-300700 filed on Oct. 15, 2002.

### FIELD OF THE INVENTION

The present invention relates to a multi-layer board capable of high-density mounting, a production method of the multi-layer board, and a mobile device having the multi-layer board.

### BACKGROUND OF THE INVENTION

As miniaturization and weight saving of an electronic device have been developed, miniaturization of an electronic component and high-density mounting in a multi-layer board are thereby desired. In a mobile device such as a cell phone, a multi-layer board with many components is particularly required to be contained within a limited small space.

Mounting many components on a multi-layer board conventionally requires enlarging loaded superficial dimensions of the board, by enlarging the board itself or piling up plural boards. However, enlarging of the board and its superficial dimensions results in increasing a size of the product. Piling up of the boards results in involving connectors for electrical connection. This thereby exhibits problems in the size of the product or a cost of the product. As another countermeasure, folding of a flexible substrate can increase loaded superficial dimensions. However, this involves difficulty in piling up flexible substrates and in increasing density of signal lines.

### SUMMARY OF THE INVENTION

It is an object of the present invention to provide a multi-layer board capable of high-density mounting, a production method of the multi-layer board, and a mobile device having the multi-layer board.

To achieve the above object, a production method for a multi-layer board comprises the following. A conductive pattern is formed on at least one surface of a resin film made of thermoplastic resin. With sandwiching at least one release film in a given region, a plurality of resin films that include the resin film that is provided with the conductive pattern are piled up. A pile of the resin films including the release film is heated and pressurized with a press mold so that the resin films mutually adhere to form a multi-layer board. A component is mounted on a surface of the multi-layer board. The release film, a first separation board that is a first portion of the multi-layer board located on the release film, and a second separation board that is a second portion of the multi-layer board located under the release film are separated to remove the release film. Another component is mounted on released surfaces of the first and second separation boards in a state where at least one separation board of the first and second separation boards is folded at an angle relative to a position prior to being folded.

Thus, when the resin films are piled, the release film is sandwiched in the given region. Resin films having the release film therebetween do not adhere to each other after being heated and pressurized, so that the resin films can be easily separated from the release film. At least one of the separated boards is then folded at an angle relative to a position prior to being separated, so that released surfaces of the two separation boards are generated. The released surfaces are available for mounting of an additional component. This results in enabling high-density mounting without enlarging superficial dimensions of the multi-layer board itself and adding a new board. Folding the separation board leads to responding to requirement in designing of a product. In particular, the above multi-layer board is suitable for use in a mobile device that has various outer appearances and functions.

### BRIEF DESCRIPTION OF THE DRAWINGS

The above and other objects, features, and advantages of the present invention will become more apparent from the following detailed description made with reference to the accompanying drawings. In the drawings:

FIGS. 1A to 1E are sectional views explaining a production method of a multi-layer board according to a first embodiment of the present invention;

FIG. 2 is a schematic plan view of a multi-layer board being loaded with components according to the first embodiment;

FIGS. 3A to 3C are sectional views explaining a production method to a stage where components are mounted on released surfaces of separation boards at the second mounting processing according to the first embodiment;

FIG. 4 is a sectional view showing a multi-layer board being loaded with a reinforcing member and a spacer according to the first embodiment;

FIGS. 5A to 5E are sectional views explaining a production method of a multi-layer board according to a second embodiment of the present invention;

FIG. 6 is a schematic plan view additionally explaining a slit according to the second embodiment;

FIG. 7 is a sectional view showing a multi-layer board after the second mounting processing according to the second embodiment; and

FIGS. 8A, 8B are sectional views of other instances of a multi-layer board.

### DETAILED DESCRIPTION OF THE PREFERRED EMBODIMENTS

Embodiments of the present invention will be explained based on drawings.

(First Embodiment)

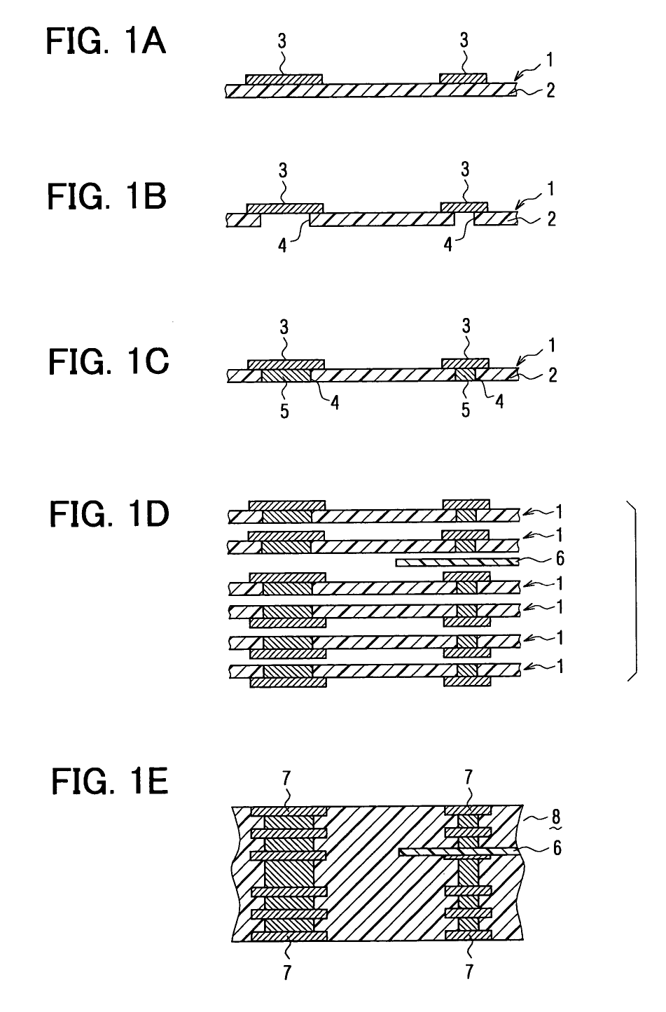

FIGS. 1A to 1E are sectional views explaining a production method of a multi-layer board according to a first embodiment of the present invention.

As shown in FIG. 1A, a one-sided conductive pattern film 1 is formed of a resin film 2 and conductive patterns 3. The conductive pattern 3 is formed by etching conductive foil that is attached on one side of the resin film 2. The resin film 2 can be made of a 25 to 100 μm resin film including 65 to 35 weight % PEEK (PolyEther-Ether-Ketone) and 35 to 65 weight % PEI (Poly-Ether-Imide). The conductive foil is made of a foil of low-resistance metal that includes at least one of gold, silver, copper, and aluminum, or desirably a foil of copper that is inexpensive and migration-free. Formation of the conductive patters can adopt a printing method instead of etching.

After the conductive patterns 3 are formed on the resin film 2 as shown in FIG. 1A, via holes 4 having bottoms on the back surface of the conductive patterns 3, as shown in FIG. 1B, by radiating carbon dioxide laser from a lower side of FIG. 1B. Formation of the via holes 4 can use UV-YAG laser or excimer laser instead of the carbon oxide laser. other formation of the via holes 4 can include mechanical formation such as processing using a drill. However, since formation requires a small diameter and prevention of damaging the conductive patterns, processing using the laser may be the best choice.

After the via holes 4 are formed, conductive paste 5 is filled within the via holes 4 as shown in FIG. 1C. The conductive paste 5 is made by mixing and kneading particles of metal such as copper (Cu), silver (Ag), or tin (Sn) with organic solvent. The conductive paste 5 can additional include, as needed, low-melting-point glass frit, organic resin, or inorganic filler. The conductive paste 5 is filled within the via holes 4 with a not-shown screen printer or dispenser.

After the conductive paste 5 is filled within the via holes 4, a plurality of one-sided conductive pattern films 1 are piled up (six films in this embodiment) as shown in FIG. 1D. Here, three films 1 upper from the center of the pile have conductive patterns in their upper sides in FIG. 1D, while the other three films 1 lower from the center of the pile have conductive patterns in their lower sides in FIG. 1D.

A release film 6 is inserted in a given region between the second and third films 1 from the top of the pile. The release film 6 is made of polyimide. Here, the polyamide has a melting point that is higher than a temperature of later-described heating/pressurizing processing. The polyamide exhibits small reduction in an elastic modulus, relative to temperature increasing. The release film 6 thereby develops an adhesion-resisting characteristic to the resin film 2 while the thermoplastic member of the resin film 2 constituting the one-sided conductive pattern film 1 is softened by the heating/pressurizing processing.

The release film 6 is 20 μm thick, so that a thickness difference takes place in the pile even though the difference is a minor. Accordingly, the conductive pattern 3 of the one-sided conductive pattern film 1 that faces the release film 6 is preferably etched to be thin enough to set off the thickness difference. As a result, thickness of the pile becomes almost even so that the heating/pressurizing processing can evenly execute heating and pressurization over the enter pile. Here, the release film 6 can be made of high heat resistant resin such as polytetra-fluoro-ethylene instead of polyimide. Although the release film 6 in this embodiment is inserted between the second and third films from the top of the pile, the release film 6 can be differently inserted without being limited to an instance of this embodiment.

After the one-sided conductive pattern films 1 are piled as shown in FIG. 1D, a press mold of a heating press machine (not shown) heats and pressurizes the pile from both the top and bottom sides of the pile to form a multi-layer board. In this embodiment, the heating/pressurization processing is executed under a condition of a temperature of 250 to 350° C. and a pressure of 1 to 10 MPa. Between the press mold and the surfaces of the pile, a buffering member (not shown) having buffering effect can be inserted to prevent the conductive patterns 3 from being displaced. Furthermore, between the buffering member and the pile and between the buffering member and the press mold, a release member (not shown) made of polyimide or the like can be disposed for the heating/pressurizing processing in order to enhancing releasing therebetween.

Through the above stages, each resin film 2 is fused and combined with having inter-layer electric connection between the adjoining conductive patterns 3 via the conductive paste 5 within the via holes 4. As a result, as shown in FIG. 1E, a multi-layer board 8 is formed as having lands 7 of the conductive patterns 3 on its top and bottom surfaces.

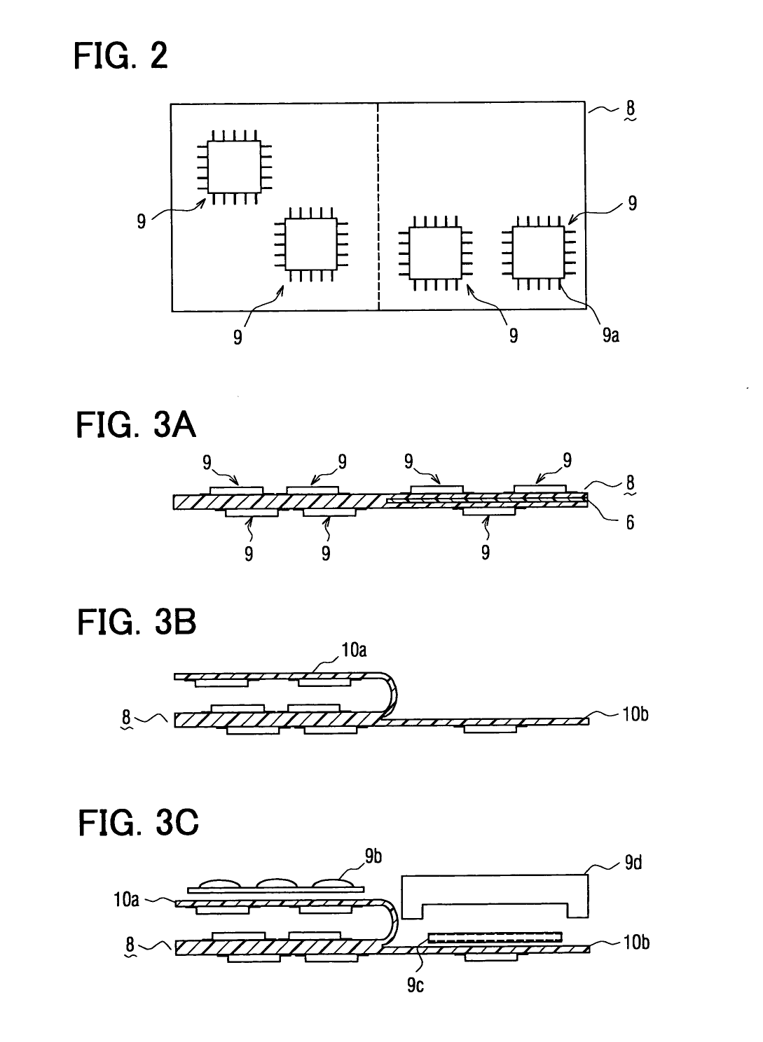

In the next place, high-density mounting of a multi-layer board 8, a feature of this embodiment, will be explained with reference of FIGS. 2, 3A to 3C. A release film 6 is disposed in half right-sided from a broken line shown in FIG. 2 showing a plan view of the multi-layer board 8. FIGS. 3A to 3C are sectional views explaining a production method. FIG. 3A is a sectional view showing a stage where components are mounted on the two top and bottom surfaces of the multi-layer board 8 after the first mounting processing. FIG. 3B is a sectional view showing a stage where the release film 6 is removed and one separation board is folded. FIG. 3C is a sectional view showing a stage where components are mounted on the released surfaces of the separation board after the second mounting processing. In FIGS. 3A to 3C, the conductive patterns 3, via holes 4, conductive paste 5, and lands 7 of the multi-layer board 8 that are shown in FIGS. 1A to 1E are expediently eliminated.

As the first mounting processing, components 9 such as an IC chip are mounted on the two top and bottom surfaces of the multi-layer board 8 as shown in FIGS. 2 and 3A. Leads 9a of the components 9 are mounted as facing the lands 7 (not shown) corresponding to circuit electrodes of the multi-layer board 8. Between the lands 7 and leads 9a, bonding material (not shown) such as solder is previously disposed on at least one of the lands 7 and leads 9a. In this stage, reflow-soldering or the like is executed to electrically and mechanically connect the lands 9a and leads.

After the components 9 are mounted on the multi-layer board 8, the release film 6 and portions of the board facing the two top and bottom surfaces of the release film 6 are separated in a region, where the release film 6 is disposed, by pulling and peeling off the release film 6. Here, the portions of the board are named as separation boards 10a, 10b. The separation board 10a is folded by approximately 180 degrees to an original disposition of its own. Namely, the folded separation board 10a is disposed as being substantially parallel with the left-sided half (surface) of the multi-layer board 8 where no release film 6 is disposed. Folding the separation board 10a by approximately 180 degrees leads to not only decreasing a size in a piling direction in comparison with adding an additional board, but also making it easier to mounting a component on the released surface. Folding the separation board 10a by a given angle can be executed along with or after being separated from the release film 6.

Here, separation between the release film 6 and the separation board 10a is executed from the right side edge of the multi-layer board 8. When the separation board 10a is thin as having a few layers, the separation board 10a is folded by applying force only to the separation board 10a itself. By contrast, the separation board 10a is thicker than the preceding, the separation board 10a is folded by heating a portion of the separation board 10a that is to be curved along with applying force to the separation board 10a. When the heating is applied, heating should be controlled so that no influence is generated on the components 9 and connecting members between the leads 9a and lands 7. Here, the release film 6 is removed after being separated from the separation boards 10a, 10b.

As the second mounting processing, as shown in FIG. 3C, components 9 are mounted on the released surfaces of the separation boards 10a, 10b of the multi-layer board 8. In FIG. 3C, as an instance for mobile device use, a sheet key 9b is mounted on the released surface of the separation board 10a, while an LCD connector 9c and an LCD module 9d are mounted on the released surface of the separation board lob.

Here, the left-sided portion of the multi-layer board has more layer than the right-sided portion. In the left-sided portion, a control circuit having high-density signal lines such as CPU and memories are disposed, while in the right-sided portion an LCD control circuit is disposed. This structure can be thereby applied to use for a cell phone. Thus, outer appearance and use of the components 9 mounted on the released surfaces of the separation boards 10a, 10b can determine circuit patterns of the multi-layer board 8, inserted regions and the number of the release films 6 in the pile, and a folding angle between the separation boards 10a, 10b. In this embodiment, a combined circuit structure of the 180-degree-folded separation board 10a and the facing board of the multi-layer board 8 can restrict intrusion of an external noise. This results in enabling the structure of the embodiment to be suitably applied to a wireless circuit.

As explained above, adopting of structure of the multi-layer board 8 of this embodiment can increase the superficial dimensions for the circuit-mounting without adding a new board or enlarging superficial dimensions of the multi-layer board 8 itself. Consequently, a multi-layer board 8 capable of high-density mounting can accommodate a large component 9 such as an LCD module 9d. As a result, the multi-layer board 8 of this embodiment is capable of high-density mounting and suitable for use of cell phones or the like.

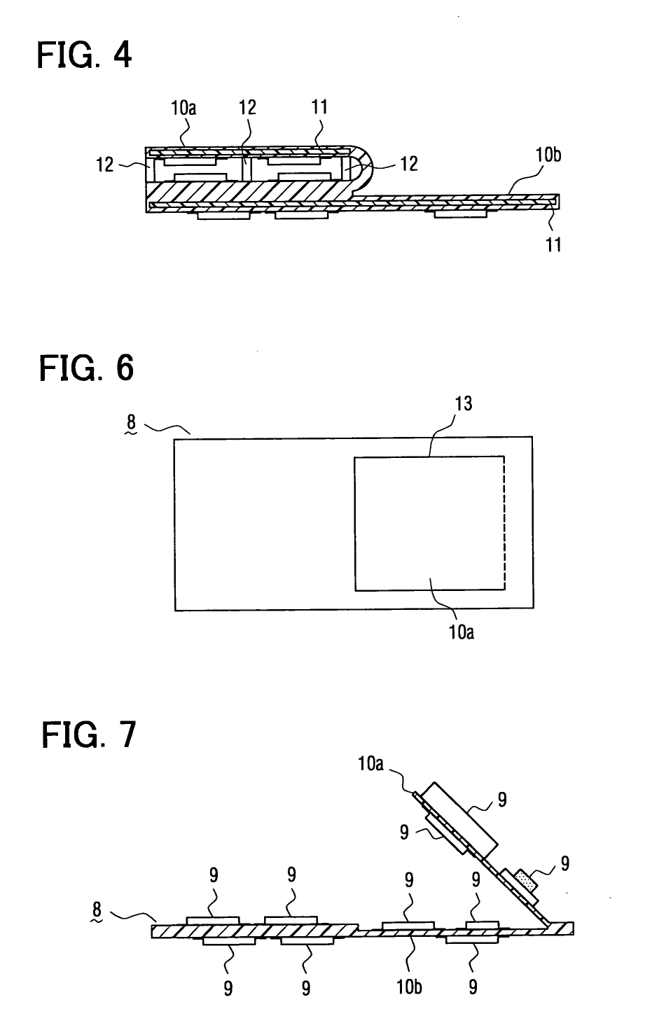

As explained above, the sheet key 9b is mounted on the released surface of the separation board 10a that is folded at the angle of approximately 180 degrees. Here, rigid structure is preferably secured for inhibiting stress from being concentrated on the curved portion of the separation board 10a. In detail, as shown in FIG. 4, glass epoxy resin or the like can be previously disposed inside the multi-layer board 8 as a reinforcing member 11. Here, the reinforcing member should not be disposed at a position where the release film 6 is inserted and at the curved portion of the separation board 10a for securing easiness of folding the board.

Furthermore, as shown in FIG. 4, spacers 12 can be disposed at spaces, between the separation board 10a and the facing board of the multi-layer board 8, where no components 9 are mounted. This can decrease stress that is generated at the curved portion of the separation board 10a when force is applied to the board 10a. The spacers 12 can be a type for fixing the board 10a not to be displaced or a type for functioning buffer effect by its own elastic deformation.

Furthermore, a melting point of the bonding material at the second mounting processing is preferably lower than that at the first mounting processing. This prevents the bonding material used at the first mounting processing from re-melting at the second mounting processing. The bonding material at the second mounting processing can be a conductive adhesive or the like that can be bonded at a lower temperature.

(Second Embodiment)

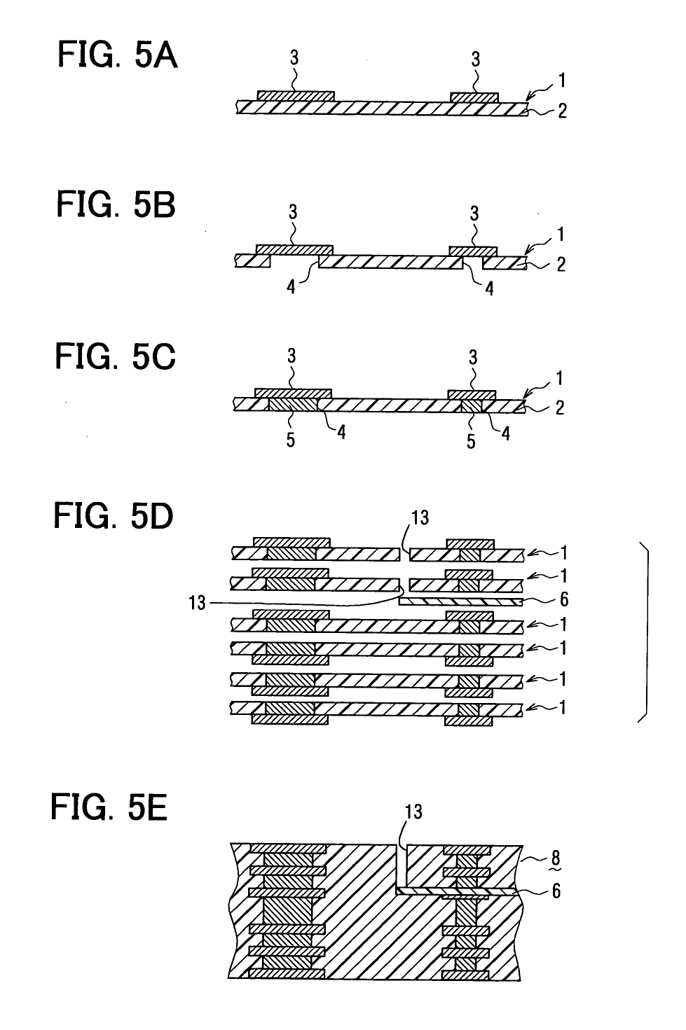

A second embodiment of the present invention will be explained with reference to FIGS. 5A to 5E, 6, 7. A multi-layer board 8 of the second embodiment has many features common to that of the first embodiment. The common portions are thereby eliminated from explanation while a different portion is explained in detail.

The different portion is that a one-sided conductive pattern film 1 has a slit that becomes a starting edge at which a release film 6 and board 10a, 10b are separated.

A production method of the multi-layer board 8 in the second embodiment shown in FIGS. 5A to 5C is almost same as that in the first embodiment shown in FIGS. 1A to 1C.

As shown in FIG. 5D, six one-sided conductive pattern films 1 and a release film 6 are piled up. The release film 6 is inserted between the second and third films 1 from the top of the pile, like the first embodiment. By contrast, unlike the first embodiment, a slit 13 is formed in resin films 2.

The slit 13 is formed, for instance, by radiating laser to the resin film 2. The slit 13 can be formed with a drill or punch. A cutting line of the slit 13 can be formed as a continuous line or a discontinuous line with given intervals. In either case, strength in a region around the line is low, so that even minor force to the separation boards 10a, 10b can enable a slit 13 to be effective as a separator all over the region.

A width of the slit 13 is preferably formed as being less than a thickness of each resin film 2. Formation position of the slit 13 is the same in the surfaces of the resin films 1. The slit 13 is thereby continuously formed to the depth of the pile where the release film 6 is disposed (inserted) as shown in FIG. 5D.

The slit 13 becomes a starting edge for separating a release film 6 and separation boards 10a, 10b in the latter stage, and also a boundary with the other portions of the multi-layer board 8. Namely, the slit defines a region of the separation boards 10a, 10b. Therefore, unlike the first embodiment shown in FIG. 2, the edge of the release film 6 is located in a portion different from the side edge of the multi-layer board 8. For instance, as shown in FIG. 6, a slit is formed in the films 1 over (or under) the release film 6 along the three solid lines (in FIG. 6). The three solid lines correspond to an inserting region of the release film 6 that is equal to formation region of the separation boards 10a, 10b. Here, the broken line in FIG. 6 is a curved portion of the separation board 10a, so that no slit is provided.

Thus, separation boards 10a, 10b having a starting edge in a portion other than the side edge of the multi-layer board 8 are formed by forming a slit 13 in a portion precluding the side edge of the multi-layer board 8. Here, the separation boards 10a, 10b and the release film 6 can be easily separated. Furthermore, a shape of the separation boards 10a, 10b can be formed by forming the slit 13 in the same shape.

Thus, heating/pressurizing processing for the pile including the one-sided conductive pattern films 1 having the slits 13 results in producing a multi-layer board 8 having a slit 13 that penetrates from the top surface to the release film 6 in the pile direction. Since the width of the slit 13 is narrow, the slit 13 may be filled with melted adjoining resin film 2 during the heating/pressurizing processing. However, even the slit 13 is filled with the resin, the resin-filled slit 13 is mechanically weak enough to be easily separated.

In the above, the slit 13 is formed in the films 1 before the films 1 are piled up. However, the slit 13 can be also formed even after piling of the films or heating/pressurizing of the pile, for instance, by using a laser.

In the next place, the first mounting processing takes place on the surface of the multi-layer board 8. Thereafter, the separation boards 10a, 10b and the release film 6 are separated from the starting edge of the slit 13 for the release film 6 to be removed. Here, the starting edge of the slit 13 is preferably located in a portion opposite to the curved portion of the separation boards 10a, 10b. Components 9 are newly mounted on the released surfaces of the separation boards 10a, 10b as shown in FIG. 7.

As explained above, forming a slit 13 from the top surface of the pile to the depth of the release film 5 in the pile direction enables separating the release film 6 and the separation boards 10a, 10b with the slit 13 as a starting edge. Furthermore, forming the slit 13 correspondingly to formation region of the separation boards 10a, 10b leads to obtaining the desired shape of the separation boards 10a, 10b. As a result, this embodiment also enables production of a multi-layer board 8 capable of high-density mounting.

(Modification)

The present invention can be directed to other modifications without limiting to the first and second embodiments.

In the above embodiments, the resin film 2 is a thermoplastic film including 65 to 35 weight % PEEK and 35 to 65 weight % PEI. However, the resin film 2 can include only either PEEK or PEI. The resin film 2 also include only PES (Poly-EtherSulfone), PPE (Poly-Phenylene-Ether), PEN (Poly-EthylenNaphthalate), liquid crystal polymer, styrene resin having syndiotactic structure, or the like. Furthermore, the resin film 2 can be made of any mixture among the preceding resins including PEEK and PEI. Namely, what is required to any mixture is adhesion characteristic between the resin films during the heating/pressurizing processing, and heating-resistant characteristic required in a post-processing such as soldering.

In the above embodiments, one-sided conductive pattern films are adopted to be piled as a resin film. However, other members can be adopted instead, such as a core board that has one-sided conductive pattern films on its top and bottom surfaces, a processed resin film that is made of thermoplastic resin and has conductive patterns in its top and bottom surfaces. Furthermore, some resin films for the pile can be without a conductive pattern. It is explained that the via holes are filled with the conductive paste with a printing method, but other methods such as electroless plating, electrolytic plating, vapor deposit, or metal coating can be adopted for filling the conductive material within the via holes.

In the above embodiments, a via hole having a bottom is formed and filled with conductive paste as an inter-layer connection member, but a via hole penetrating a film can be formed and filled with the inter-layer connection member.

In the above embodiments, six one-sided conductive pattern films are piled, but any number of layers more than one can be adopted.

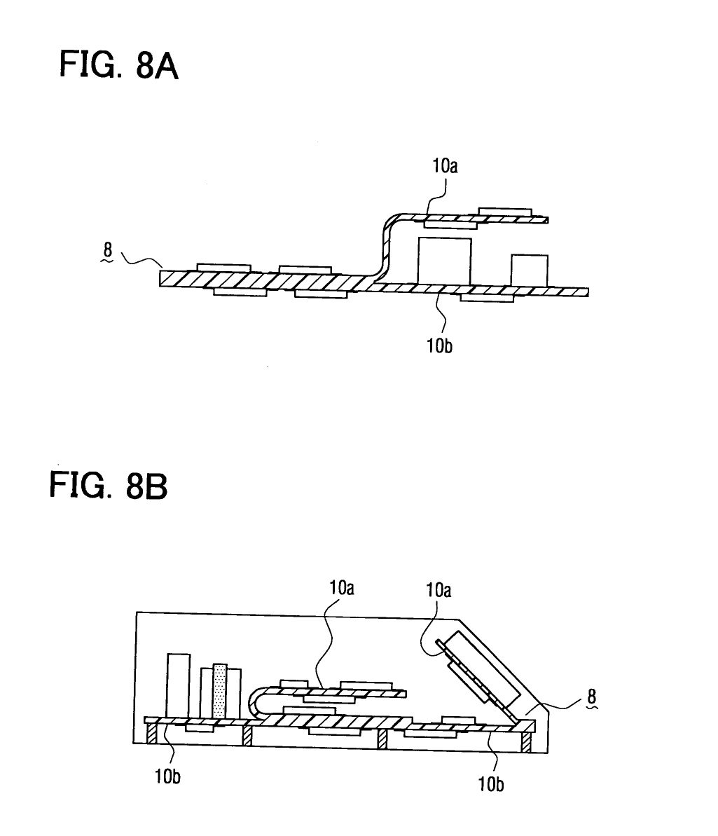

In the above embodiments, a separation board is folded at an angle of 180 degrees. However, as shown in FIG. 8A, after the separation board is once folded at an angle of 90 degrees relative to an original disposition and the second mounting processing then takes place, the separation board can be again folded as being disposed in parallel to the other separation board.

In the above embodiments, one release film is disposed between one-sided conductive pattern films for forming a multi-layer board. However, more than one release film can be disposed as shown in FIG. 8B, where two release films are used.

Furthermore, as shown in FIG. 8B, the separation boards can be folded at any angle prior to mounting of the components according to a shape of the casing of an electronic device or a shape of the mounted components.

In the above embodiments, one separation board is only folded at an angle relative to an original disposition. However, the other separation board can be simultaneously folded at an angle. Furthermore, providing plural release films enables production of a multi-layer board having more than two folded separation boards.

It will be obvious to those skilled in the art that various changes may be made in the above-described embodiments of the present invention. However, the scope of the present invention should be determined by the following claims.

What is claimed is:

1. A production method for a multi-layer board, comprising:
a pattern forming step of forming a conductive pattern on at least one surface of a resin film made of thermoplastic resin;
a piling step of piling up, with sandwiching at least one release film in a given region, a plurality of resin films that include the resin film that is provided with the conductive pattern;
a heating and pressurizing step of heating and pressurizing with a press mold a pile of the resin films including the release film so that the resin films mutually adhere to form the multi-layer board;
a first mounting step of mounting a component on a surface of the multi-layer board;
a separating step of separating the release film, a first separation board, and a second separation board to remove the release film, wherein the first separation board is a first portion of the multi-layer board that is located on the release film while the second separation board is a second portion of the multi-layer board that is located under the release film; and
a second mounting step of mounting a component on at least one released surface of the first and second separation boards in a state where at least one separation board of the first and second separation boards is folded at an angle relative to a position prior to being separated.

2. The production method for a multi-layer board according to claim 1, further comprising:
a slit forming step of forming a slit so that the slit is disposed from one surface of the multi-layer board to a surface of the release film perpendicularly to the surface of the multi-layer board.

3. The production method for a multi-layer board according to claim 2,
wherein, when a formation portion where the first and second separation boards are formed within the multi-layer board precludes a side edge of the multi-layer board, the slit is formed so that the slit is along at least a part of a peripheral edge of the formation portion.

4. The production method for a multi-layer board according to claim 2,
wherein the slit is formed so that the slit is being continuously cut within the multi-layer board.

5. The production method for a multi-layer board according to claim 2,
wherein the slit is formed so that the slit is being discontinuously cut within the multi-layer board.

6. The production method for a multi-layer board according to claim 1,
wherein the first and second separation boards are separated from a side edge of the multi-layer board as a starting edge.

7. The production method for a multi-layer board according to claim 1,
wherein the first and second separation boards are separated from a slit as a starting edge, wherein the slit is formed approximately perpendicularly to one surface of the multi-layer board from the one surface of the multi-layer board to a surface of the release film.

8. The production method for a multi-layer board according to claim 1,
wherein a spacer is provided at least one space of a first space and a second space, wherein the first space is between the separated first and second separation boards while the second space is between the surface of the multi-layer board and one of the separated first and second separation boards.

9. The production method for a multi-layer board according to claim 1,
wherein in the piling step a reinforcing member is additionally provided in a certain region between the resin films, wherein the certain region precludes the given region where the release film is sandwiched and a region where the folded separation board is curved.

10. The production method for a multi-layer board according to claim 1,
wherein the release film has a melting temperature that is higher than a temperature at which the heating and pressurizing step is executed.

11. A multi-layer board comprising:
a plurality of conductive patterns piled with having resin films, made of thermoplastic resin, therebetween; and
two separation boards of a first and a second separation boards,
wherein, before being heated and pressurized, the first and the second separation boards are located at an upper side and a lower side, respectively, of at least one release film that is sandwiched in a region between two of the resin films,
wherein, after being heated and pressurized, the first and the second separation boards and the release film are separated for the release film to be removed,
wherein one of the two separation boards is folded at an angle relative to a position prior to being separated, and
wherein a component can be mounted on at least one released surface of the two separation boards;

12. The multi-layer board according to claim 11,
wherein the one of the two separation boards is folded at an angle of approximately 180 degrees relative to a position prior to being separated.

13. The multi-layer board according to claim 11,
wherein a spacer is provided at least one space of a first space and a second space, wherein the first space is between the separated first and second separation boards while the second space is between the surface of the multi-layer board and one of the separated first and second separation boards.

14. The multi-layer board according to claim 11, further comprising:
a reinforcing member provided in a certain region between the resin films, wherein the certain region precludes a first region where the release film was sandwiched before being separated and a second region where the folded separation board is curved.

15. A mobile device comprising:
a multi-layer board, wherein the multi-layer board includes,
a plurality of conductive patterns piled with having resin films, made of thermoplastic resin, therebetween, and
two separation boards of a first and a second separation boards,
wherein, before being heated and pressurized, the first and the second separation boards are located at an upper side and a lower side, respectively, of at least one release film that is sandwiched in a region between the resin films,
wherein, after being heated and pressurized, the first and the second separation boards and the release film are separated for the release film to be removed, and
wherein one of the two separation boards is folded at an angle relative to a position prior to being separated; and
a component mounted on at least one released surface of the two separation boards of the multi-layer board.

16. The mobile device according to claim 15,
wherein a sheet key is disposed on the released surface of one of the separated two separation boards that is folded at an angle of approximately 180 degrees relative to a position prior to being separated, and
wherein an LCD connector and an LCD module are disposed on the released surface of the other of the separated two separation boards.

17. A multi-layer board produced by a method that comprises:
a pattern forming step of forming a conductive pattern on at least one surface of a resin film made of thermoplastic resin;
a piling step of piling up, with sandwiching at least one release film in a given region, a plurality of resin films that include the resin film that is provided with the conductive pattern;
a heating and pressurizing step of heating and pressurizing with a press mold a pile of the resin films including the release film so that the resin films mutually adhere to form the multi-layer board;
a first mounting step of mounting a component on a surface of the multi-layer board;
a separating step of separating the release film, a first separation board, and a second separation board to remove the release film, wherein the first separation board is a first portion of the multi-layer board that is located on the release film while the second separation board is a second portion of the multi-layer board that is located under the release film; and
a second mounting step of mounting a component on at least one released surface of the first and second separation boards in a state where at least one separation board of the first and second separation boards is folded at an angle relative to a position prior to being separated.

18. A mobile device comprising:
a multi-layer board; and
a component mounted on at least one of two released surfaces of two separation boards of the multi-layer board,
wherein the multi-layer board produced by a method that includes:
a pattern forming step of forming a conductive pattern on at least one surface of a resin film made of thermoplastic resin;
a piling step of piling up, with sandwiching at least one release film in a given region, a plurality of resin films that include the resin film that is provided with the conductive pattern;
a heating and pressurizing step of heating and pressurizing with a press mold a pile of the resin films including the release film so that the resin films mutually adhere to form the multi-layer board;
a first mounting step of mounting a component on a surface of the multi-layer board;
a separating step of separating the release film, a first separation board of the two separation boards, and a second separation board of the two separation boards to remove the release film, wherein the first separation board is a first portion of the multi-layer board that is located on the release film while the second separation board is a second portion of the multi-layer board that is located under the release film; and
a folding step of folding at least one separation board of the two separation boards, at an angle relative to a position prior to being separated, to form the released surfaces of the two separation boards.
